(19) United States
(12) Patent Application Publication
(10) Pub. No.: US 2015/0102799 A1
(43) Pub. Date: Apr. 16, 2015

(54) JITTER DETERMINATION OF NOISY ELECTRICAL SIGNALS

(71) Applicant: Nvidia Corporation, Santa Clara, CA (US)

(72) Inventor: Hans Wolfgang Schulze, Santa Clara, CA (US)

(73) Assignee: Nvidia Corporation, Santa Clara, CA (US)

(21) Appl. No.: 14/054,027

(22) Filed: Oct. 15, 2013

(51) Int. Cl. G01R 17/00

(52) U.S. Cl. CPC G01R 17/00
USPC 324/76.11

(57) ABSTRACT

A jitter analysis system includes an electronic circuit having a noisy electrical signal with jitter along a baseline of the signal. The jitter analysis system also includes a sampling unit coupled to the noisy electrical signal that provides waveform samples of the noisy electrical timing signal and a jitter detection unit coupled to the sampling unit that provides baseline crossings of the noisy electrical signal, wherein the baseline crossings are determined from a selection of the waveform samples proximate the baseline of the signal. A jitter determination method is also provided.

### TECHNICAL FIELD

This application is directed, in general, to jitter determination and, more specifically, to a jitter analyzer, a jitter determination method and a jitter analysis system.

### BACKGROUND

In general, electrical jitter may be defined as an undesired variation in the periodicity of an intended periodic electrical signal. Additionally, categorizing this type of jitter may include the areas of basic, cycle-to-cycle and long-term jitter. In particular, electrical jitter associated with clocking circuits may cause logic circuits to malfunction if critical timing parameters are not adequately determined. Signals having large amounts of electrical noise or sporadic frequency content provide a more challenging environment for determining critical jitter parameters.

### SUMMARY

Embodiments of the present disclosure provide a jitter analyzer, a jitter determination method and a jitter analysis system.

In one embodiment, the jitter analyzer includes a sampling unit coupled to a noisy electrical waveform having jitter along a waveform baseline and configured to provide waveform samples of the noisy electrical waveform. Additionally, the jitter analyzer also includes a jitter detection unit coupled to the sampling unit and configured to provide baseline crossings for the noisy electrical waveform, wherein the baseline crossings are determined from a selection of the waveform samples proximate the waveform baseline.

In another aspect, the jitter determination method includes sampling a noisy electrical waveform having jitter along a waveform baseline to provide waveform samples of the noisy electrical waveform. The jitter determination method also includes providing baseline crossings for the noisy electrical waveform, wherein the baseline crossings are determined from a selection of the waveform samples proximate the waveform baseline. The jitter determination method further includes determining a jitter characteristic from the baseline crossings.

In yet another aspect, the jitter analysis system includes an electronic circuit having a noisy electrical signal with jitter along a baseline of the signal. The jitter analysis system also includes a sampling unit coupled to the noisy electrical signal that provides waveform samples of the noisy electrical timing signal and a jitter detection unit coupled to the sampling unit that provides baseline crossings of the noisy electrical signal, wherein the baseline crossings are determined from a selection of the waveform samples proximate the baseline of the signal.

The foregoing has outlined preferred and alternative features of the present disclosure so that those skilled in the art may better understand the detailed description of the disclosure that follows. Additional features of the disclosure will be described hereinafter that form the subject of the claims of the disclosure. Those skilled in the art will appreciate that they can readily use the disclosed conception and specific embodiment as a basis for designing or modifying other structures for carrying out the same purposes of the present disclosure.

### BRIEF DESCRIPTION

Reference is now made to the following descriptions taken in conjunction with the accompanying drawings, in which:

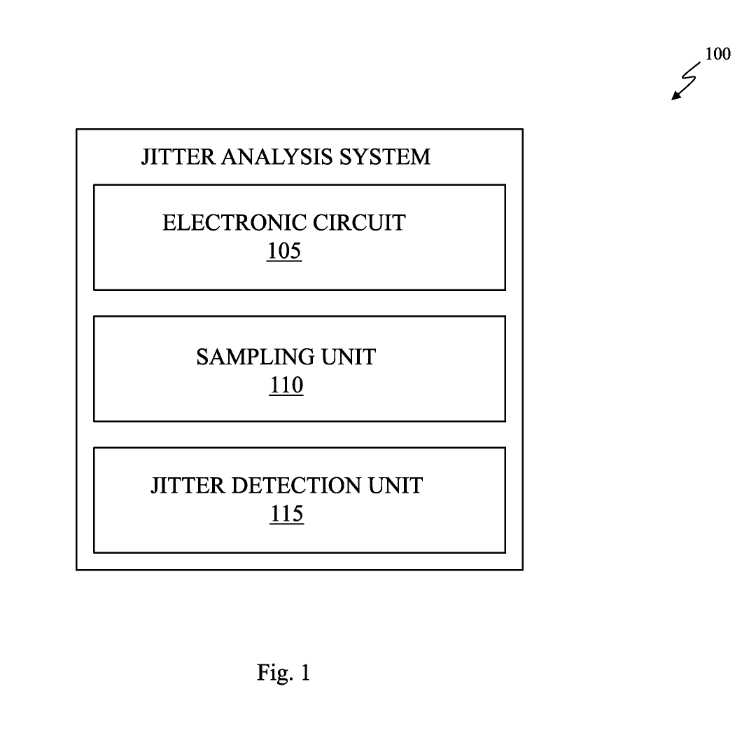

FIG. 1 illustrates a block diagram of an embodiment of a jitter detection system constructed according to the principles of the present disclosure;

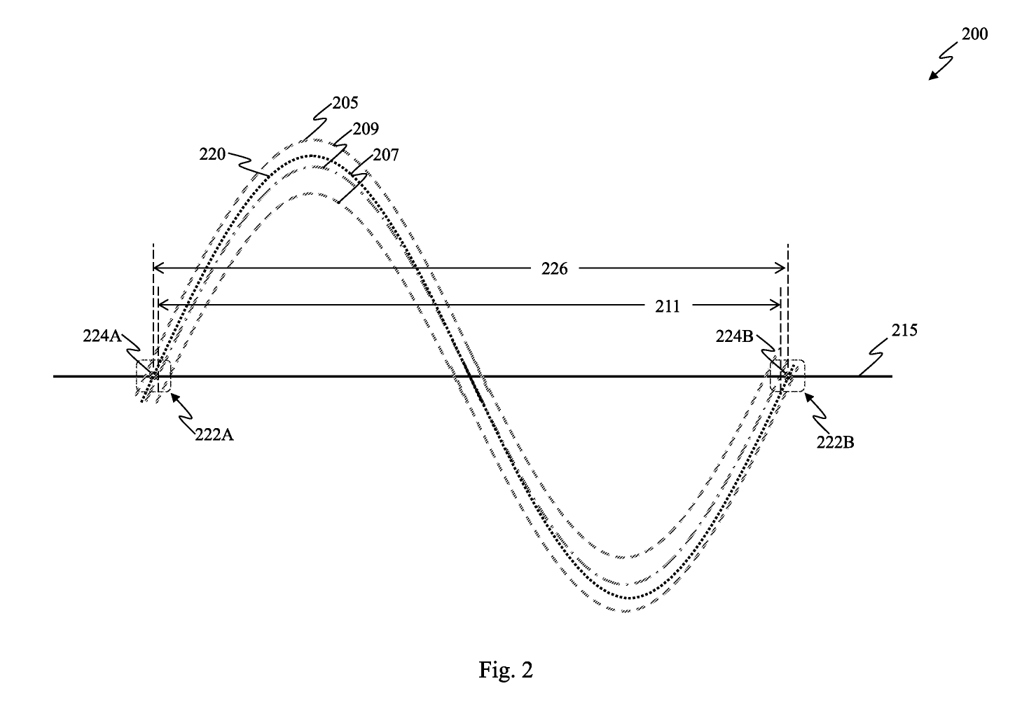

FIG. 2 illustrates an example of a noisy electrical waveform as may be analyzed by the jitter detection system of FIG. 1;

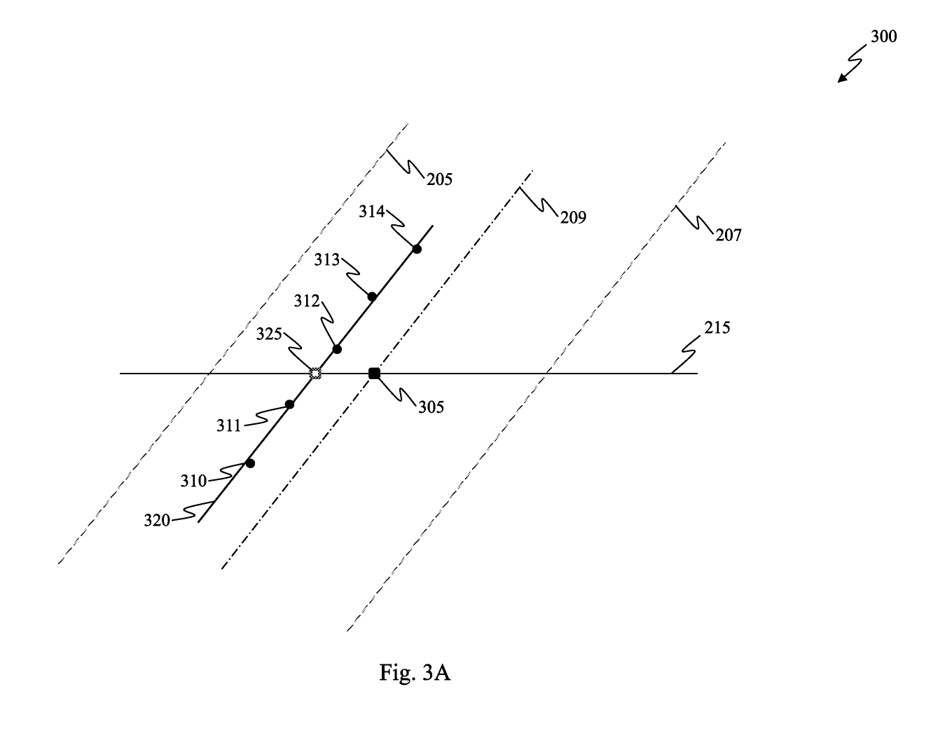

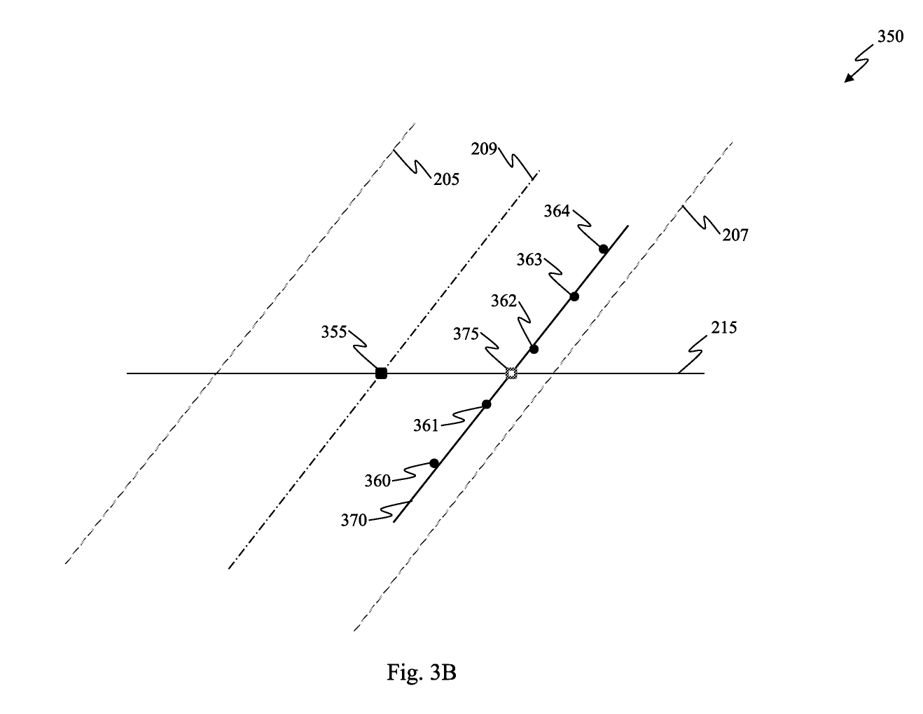

FIGS. 3A and 3B illustrate examples of baseline crossing areas corresponding to baseline crossing areas of FIG. 2; and

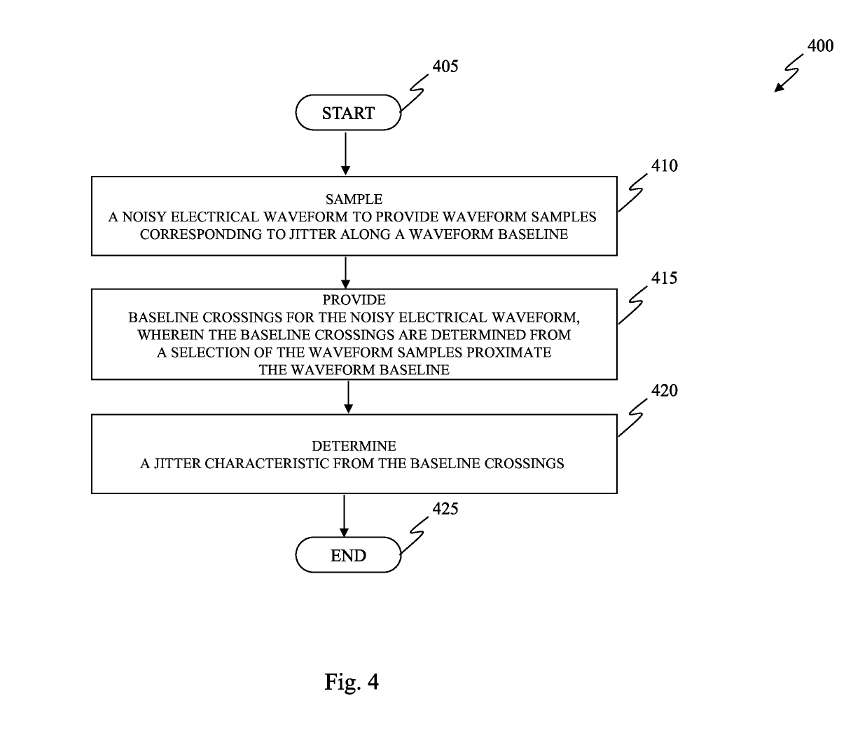

FIG. 4 illustrates a flow diagram of an embodiment of a jitter determination method carried out according to the principles of the present disclosure.

### DETAILED DESCRIPTION

A number of current approaches for measuring jitter have problems with electrical signals that contain high amounts of electrical noise or sporadic frequency content. These approaches often provide erroneous or indeterminate results due to high levels of input noise mixed with a primary signal that is being measured. Embodiments of the present disclosure reduce the impact of instantaneous peak-to-peak noise that is experienced at the baseline crossing area of a noisy waveform, as well as possible multiple excursions of the noisy waveform over a baseline crossing due to high-frequency noise.

Therefore, embodiments of the present disclosure provide reduction of false measurements to an acceptable level and provide a higher confidence level than current approaches. Additionally, substantially noiseless calibration-grade signals, employed as a verification tool, produce extremely small jitter values while matching or slightly improving readings with respect to other techniques. Embodiments of the present disclosure may be implemented in hardware, software or a combination of both.

FIG. 1 illustrates a block diagram of an embodiment of a jitter detection system, generally designated 100, constructed according to the principles of the present disclosure. The jitter detection system 100 includes an electronic circuit 105 that employs a jitter analyzer, which includes a sampling unit 110 and a jitter detection unit 115.

The electronic circuit 105 provides a noisy electrical signal with jitter along a baseline of the signal. The sampling unit 110 is coupled to the noisy electrical signal and provides waveform samples of the noisy electrical signal. Correspondingly, the jitter detection unit 115 is coupled to the sampling unit and provides baseline crossings of the noisy electrical signal, wherein the baseline crossings are determined from a selection of the waveform samples proximate the baseline of the signal.

In one embodiment, this technique involves using a sampling oscilloscope to capture a large quantity of noisy electrical waveforms (e.g., 100K waveforms) with an oversampling of at least ten times the primary frequency, as typically required by accepted numerical methods. Subsequently, a baseline is established for the noisy electrical signal wherein baseline crossing events may be detected by simple comparison against median limits (e.g., (average signal high−average signal low)/2+(average signal low)). Then each waveform baseline crossing selected is determined by employing the selection of the waveform samples proximate the baseline of the signal (i.e., the baseline crossing area selected).

This selection of the waveform samples (e.g., five sample points around the waveform baseline) is then employed to generate a line defined by this selection using a least squares fit or other appropriate line fitting algorithm. Generally, more than one curve or line fitting algorithm can be used depending on the number of available points and timing accuracy versus the performance requirements of the measurement. The intersection of this fitted line and the baseline establish the baseline crossing for the baseline crossing area under consideration.

Selection of successive baseline crossings in this manner may be extremely accurate since each is based on a selection of the waveform samples proximate the baseline of each noisy waveform of the signal and is not an average of sample points in the selection, but corresponds to an average of their “flight” through the baseline. This approach ensures that the baseline crossing point is determined as accurately as can be obtained using the selection. Finally, one or more of these baseline crossing points become reference points for calculating various forms of jitter characterization.

FIG. 2 illustrates an example of a noisy electrical waveform, generally designated 200, as may be analyzed by the jitter detection system 100 of FIG. 1. The noisy electrical waveform 200 includes an upper noise excursion limit 205, a lower noise excursion limit 207 and an average value 209 of the noisy electrical waveform 200, as well as an average period 211 along a baseline 215 corresponding to the average value 209. In general, the baseline 215 may correspond to a positive or negative DC voltage or a zero voltage value. Additionally, the noisy electrical waveform 200 is portrayed as substantially sinusoidal, in the illustrated example. However, the noisy electrical waveform 200 may generally be any AC waveform that oscillates around a baseline value.

Also included are waveform samples 220 of the noisy electrical signal 200 having baseline crossing areas 222A, 222B that include a first determined baseline crossing 224A and a second determined baseline crossing 224B respectively, which provide an extended jitter period 226 compared to the average period 211. Although not explicitly shown, waveform samples of the noisy electrical signal 200 may be taken that are below the average value 209 and provide determined baseline crossings for a shortened jitter period.

Embodiments of the present disclosure scour all the samples taken for each cycle of the noisy electrical signal to select a portion of those taken closest to the baseline. As discussed earlier, these are used to determine baseline crossing points (i.e., jitter reference points) and may be established on each rising and falling edge of each noisy waveform cycle. A desired jitter characteristic may be obtained through analyzing one or more of the jitter reference points.

Basic jitter may include statistics of the difference in time between two reference points. This might include minimum, maximum or average jitter, as well as population density or histogram plots to extract “bathtub tails” for further analysis. Cycle-to-cycle jitter includes statistics corresponding to a difference between two consecutive basic jitter measurements. Long-term jitter typically includes statistical trends corresponding to selection of a number of jitter points that are compared to later reference points.

FIGS. 3A and 3B illustrate examples of baseline crossing areas, generally designated 300, 350, corresponding to the baseline crossing areas 222A, 222B of FIG. 2. In each case, selections of waveform samples shown are a portion of the waveform samples 220 of FIG. 2 that are close to the baseline 215. Generally, baseline crossing areas may correspond to positive or negative crossing directions of a noisy electrical waveform.

The baseline crossing area 300 is an expansion of the baseline crossing area 222A and includes the upper noise excursion limit 205, the lower noise excursion limit 207 and the average value 209 of the noisy electrical waveform 200 along with the baseline 215 and an average baseline crossing point 305. The baseline crossing area 300 also includes a selection of waveform samples 310-314 proximate the baseline 215, a crossing line 320 fitted to the selection of waveform samples 310-314 and a jitter reference point 325 at the intersection of the crossing line 320 and the baseline 215.

Correspondingly, the baseline crossing area 350 is an expansion of the baseline crossing area 222B and includes the upper noise excursion limit 205, the lower noise excursion limit 207 and the average value 209 of the noisy electrical waveform 200 along with the baseline 215 and an average baseline crossing point 355. The baseline crossing area 350 also includes a selection of waveform samples 360-364 proximate the baseline 215, a crossing line 370 fitted to the selection of waveform samples 360-364 and a jitter reference point 375 at the intersection of the crossing line 370 and the baseline 215.

A statistical variation of this process may be plotted as a histogram to provide a population (e.g., a Gaussian distribution), which shows how extensive the jitter may be if billions of sample readings were taken. In one example, this may be displayed as bathtub tails. In telecommunications, a bit error rate (BER) may be generated from jitter measurements and characterizations (e.g., the bathtub tails), where a BER requirement of 10⁻¹² may be typical. Embodiments of the present disclosure allow approximately a million measurements to be extrapolated to 10¹² edges by performing a curve fit for this statistical mapping.

FIG. 4 illustrates a flow diagram of an embodiment of a jitter determination method, generally designated 400, carried out according to the principles of the present disclosure. The method 400 starts in a step 405 and a noisy electrical waveform is sampled to provide waveform samples corresponding to jitter along a waveform baseline, in a step 410. Then, baseline crossings for the noisy electrical waveform are provided, wherein the baseline crossings are determined from a selection of the waveform samples proximate the waveform baseline, in a step 415, and a jitter characteristic is determined from the baseline crossings, in a step 420.

In one embodiment, the noisy electrical waveform corresponds to one selected from the group consisting of a timing signal and a communications signal. In another embodiment, the baseline crossings determine a jitter characteristic for one selected from the group consisting of a basic jitter, a cycle-to-cycle jitter and a long term jitter. In yet another embodiment, the baseline crossings determine a jitter characteristic that corresponds to a bit error rate of the noisy electrical waveform.

In still another embodiment, the selection of the waveform samples proximate the waveform baseline is based on a user defined number of samples. In a further embodiment, the selection of the waveform samples proximate the waveform baseline is based on a number of samples corresponding to a line fitting requirement. In a yet further embodiment, the selection of the waveform samples proximate the waveform baseline is based on a total number of samples of the noisy electrical waveform. The method 400 ends in a step 425.

While the method disclosed herein has been described and shown with reference to particular steps performed in a particular order, it will be understood that these steps may be combined, subdivided, or reordered to form an equivalent method without departing from the teachings of the present disclosure. Accordingly, unless specifically indicated herein, the order or the grouping of the steps is not a limitation of the present disclosure.

Those skilled in the art to which this application relates will appreciate that other and further additions, deletions, substitutions and modifications may be made to the described embodiments.

What is claimed is:

1. A jitter analyzer, comprising:
a sampling unit coupled to a noisy electrical waveform having jitter along a waveform baseline and configured to provide waveform samples of the noisy electrical waveform; and
a jitter detection unit coupled to the sampling unit and configured to provide baseline crossings for the noisy electrical waveform, wherein the baseline crossings are determined from a selection of the waveform samples proximate the waveform baseline.

2. The analyzer as recited in claim 1 wherein the noisy electrical waveform corresponds to one selected from the group consisting of:
a timing signal; and
a communications signal.

3. The analyzer as recited in claim 1 wherein the selection of the waveform samples proximate the waveform baseline is based on one selected from the group consisting of:
a user defined number of samples; and
a number of samples corresponding to a linear line fit.

4. The analyzer as recited in claim 1 wherein a number of samples in the selection of the waveform samples proximate the waveform baseline is based on a total number of samples of the noisy electrical waveform.

5. The analyzer as recited in claim 1 wherein the baseline crossings determine a jitter characteristic for one selected from the group consisting of:
a basic jitter;
a cycle-to-cycle jitter; and
a long term jitter.

6. The analyzer as recited in claim 1 wherein the baseline crossings determine a jitter characteristic that corresponds to a bit error rate of the noisy electrical waveform.

7. A jitter determination method, comprising:
sampling a noisy electrical waveform having jitter along a waveform baseline to provide waveform samples of the noisy electrical waveform;
providing baseline crossings for the noisy electrical waveform, wherein the baseline crossings are determined from a selection of the waveform samples proximate the waveform baseline; and
determining a jitter characteristic from the baseline crossings.

8. The method as recited in claim 7 wherein the noisy electrical waveform corresponds to one selected from the group consisting of:
a timing signal; and
a communications signal.

9. The method as recited in claim 7 wherein the selection of the waveform samples proximate the waveform baseline is based on a user defined number of samples.

10. The method as recited in claim 7 wherein the selection of the waveform samples proximate the waveform baseline is based on a number of samples corresponding to a line fitting requirement.

11. The method as recited in claim 7 wherein the selection of the waveform samples proximate the waveform baseline is based on a total number of samples of the noisy electrical waveform.

12. The method as recited in claim 7 wherein the baseline crossings determine a jitter characteristic for one selected from the group consisting of:
a basic jitter;
a cycle-to-cycle jitter; and
a long term jitter.

13. The method as recited in claim 7 wherein the baseline crossings determine a jitter characteristic that corresponds to a bit error rate of the noisy electrical waveform.

14. A jitter analysis system, comprising:
an electronic circuit having a noisy electrical signal with jitter along a baseline of the signal;
a sampling unit coupled to the noisy electrical signal that provides waveform samples of the noisy electrical timing signal; and
a jitter detection unit coupled to the sampling unit that provides baseline crossings of the noisy electrical signal, wherein the baseline crossings are determined from a selection of the waveform samples proximate the baseline of the signal.

15. The system as recited in claim 14 wherein the noisy electrical signal corresponds to one selected from the group consisting of:
a timing signal; and
a communications signal.

16. The system as recited in claim 14 wherein the selection of the waveform samples proximate the waveform baseline is based on a user defined number of samples.

17. The system as recited in claim 14 wherein the selection of the waveform samples proximate the waveform baseline is based on a number of samples corresponding to a line fitting requirement.

18. The system as recited in claim 14 wherein the selection of the waveform samples proximate the waveform baseline is based on a total number of samples of the noisy electrical signal.

19. The system as recited in claim 14 wherein the baseline crossings determine a jitter characteristic for one selected from the group consisting of:
a basic jitter;
a cycle-to-cycle jitter; and
a long term jitter.

20. The system as recited in claim 14 wherein the baseline crossings determine a jitter characteristic that corresponds to a bit error rate of the noisy electrical signal.
